(19) United States
(12) Patent Application Publication
(10) Pub. No.: US 2007/0034966 A1
(43) Pub. Date: Feb. 15, 2007

(54) Dual gate CMOS semiconductor devices and methods of fabricating such devices

(76) Inventors: Min-Joo Kim, Seoul (KR); Jong-Ho Lee, Suwon-si (KR); Sung-Kee Han, Seongnam-si (KR); Hyung-Suk Jung, Suwon-si (KR)

Correspondence Address: HARNESS, DICKEY & PIERCE, P.L.C., P.O. BOX 8910, RESTON, VA, 20195, US

(21) Appl. No.: 11/477,558

(22) Filed: Jun. 30, 2006

(30) Foreign Application Priority Data
Jun. 30, 2005 (KR) 10-2005-0058559

(51) Int. Cl. H01L 29/94

(52) U.S. Cl. 257/369

(57) ABSTRACT

Disclosed are dual gate CMOS devices and methods for fabricating such devices. The dual gate structures are produced by forming a first gate electrode having first conductive stack on transistors of a first channel type and forming a second gate electrode having a second conductive stack on transistors of a second channel type, wherein the first and second conductive stacks have different compositions for including different work functions (Φ) in the respective transistors. At least one of the first and second conductive stacks will include metal(s) and/or metal compound(s) from which, when subjected to an appropriate thermal treatment, the metal(s) will diffuse to the interface formed between in the gate dielectric layer and the gate electrode and thereby modify the electrical properties of the associated transistors as reflected in, for example, a V_{fb} shift.

### PRIORITY STATEMENT

This application claims priority under 35 U.S.C. § 119 from Korean Patent Application No. 10-2005-0058559, filed on Jun. 30, 2005, in the Korean Intellectual Property Office, the disclosure of which is incorporated herein, in its entirety, by reference.

### BACKGROUND OF THE INVENTION

1. Field of the Invention

The invention relates to CMOS semiconductor devices utilizing metal oxide semiconductor (MOS) transistors and methods of fabricating such devices, and more particularly, to semiconductor devices having complementary metal oxide semiconductor (CMOS) configurations incorporating dual gate electrode materials specific to the respective NMOS and PMOS transistors and methods of fabricating method thereof.

2. Description of the Related Art

As semiconductor devices have become more highly integrated and design sizes of metal oxide semiconductor field effect transistors (MOSFETs) have decreased, the lengths of gates and channels formed underneath the gates have also decreased. According, modifications to the configuration and/or the dielectric material of the thin gate insulating layer have been adopted to increase the gate capacitance and to improve the operational characteristics of transistors. However, materials conventionally used in forming gate insulating layers, for example, silicon oxide or silicon oxynitride, have physical properties that limit their ability to form dielectric layers that are sufficiently thin to achieve the desired capacitance while still maintaining acceptable reliability. Accordingly, it is difficult to form a reliable thin gate insulating layer suitable for highly integrated devices using conventional dielectric materials.

One approach that has been developed for addressing the deficiencies of the conventional dielectric materials involved using materials that provided an increased dielectric constant, κ, (i.e., a high-κ material). Using high-κ materials has allowed the fabrication of dielectric layers that provide capacitance equivalent to that of a thin oxide layer while still providing satisfactory suppression of the leakage current between the associated gate electrode and channel region. However, when a high-κ material is used to form the gate insulating layer of a MOSFET, there may be a corresponding decrease in the electron mobility in a channel region below the gate insulating layer, more specifically, a gate dielectric layer, that has been attributed to a plurality of bulk traps and interface traps created at the interface between the substrate and the gate insulating layer. Also, compared with gate insulating layers utilizing conventional silicon oxide or silicon oxynitride dielectric layers, the threshold voltage (Vₜ) of transistors incorporating high-κ gate dielectric layers can exhibit undesirable increases.

Various models have been proposed for explaining describe the above increase of the threshold voltage depending on types of high-κ materials. On such model was presented in an article by C. Hobbes, et al., Symp. on VLSI Tech. Digest, p. 9 (2003) (“Hobbes”), that attributed the threshold voltage increases to Fermi-level pinning resulting from a metal-silicon bond, for example, a Hf—Si bond in the case of a HfO₂ dielectric, or a metal-silicon-oxygen bond, for example, a Al—Si—O bond in the case of an alumina (Al₂O₃) dielectric, created at the interface between the semiconductor region, for example, a silicon channel region, and the metal oxide that is being utilized as the high-κ material. According to Hobbes, in the case of HfO₂, the Fermi-level pinning occurs in a region close to a conduction band of silicon due to a Si—Hf bond and, as a result, the threshold voltage of the P-channel MOS (PMOS) transistors exhibit abnormal increases. Conversely, also according to Hobbes, in the case of Al₂O₃, the Fermi-level pinning occurs in a region close to a valence band of silicon due to a Si—O—Al bond, producing an abnormal increase in the Vₜ of the NMOS transistors.

Using the Fermi-level pinning approach, a dual gate insulation structure, including HfO₂ for the gate insulating layer of the N-channel MOS (NMOS) transistors and Al₂O₃ for the gate insulating layer of the PMOS transistors, can decrease the respective threshold voltages of the NMOS transistors and the PMOS transistors to appropriate levels. However, in order to fabricate such a dual gate insulation structure, an etching process is required for removing designated regions of a first gate insulating layer from the substrate to provide areas for the formation of the second gate insulating material layer on the substrate. The forming and etching procedures for the dual gate insulation structure may reduce the reliability of the gate insulating layer remaining on the substrate, and the equivalent oxide thickness of the gate insulating layer may increase.

### SUMMARY OF THE INVENTION

Example embodiments of the invention include CMOS semiconductor devices that exhibit improved threshold voltages for both the NMOS and PMOS transistors incorporated in the CMOS device in which the NMOS and PMOS transistors are fabricated to have different and channel type specific work functions (Φ).

An example embodiment of a CMOS semiconductor device according to the invention includes: a first MOS transistor that has a first channel of a first conductivity type and includes a first gate insulating layer and a first gate electrode formed on the first gate insulating layer, wherein the first gate electrode includes a first metal alloy layer composed of a first metal and a second metal; and a second MOS transistor with a second channel of a second conductivity type. Other example embodiments may include first gate electrodes in which a polysilicon layer is formed on the first metal alloy layer.

Example embodiments of the first MOS transistor, in which the first gate electrode includes the first metal alloy layer, may exhibit a lower threshold voltage than a corresponding MOS transistor in which the gate electrode includes a metal layer of one of the first metal or the second metal rather than an alloy of the two metals. Example embodiments of the first gate electrode may also include a metal oxide thin film formed on the first metal alloy layer.

Example embodiments of the second MOS transistor may include a second gate insulating layer and a second gate electrode formed on the first gate insulating layer wherein the second gate electrode incorporates a metal layer formed of one of the first and second metals. Example embodiments of the second gate electrode may also include a polysilicon layer formed on the metal layer.

Example embodiments of the second MOS transistor may also include a third gate insulating layer and a third gate electrode that includes a second metal alloy layer formed on the third gate insulating layer. Example embodiments of the third gate electrode may further include a polysilicon layer formed on the second metal alloy layer. The third gate electrode may further include a third metal alloy layer formed between the second metal alloy layer and the polysilicon layer in which the second and third metal alloy layers may have different compositions.

Other example embodiments of the invention include CMOS devices including a first MOS transistor that has a first channel of a first conductivity type, a first gate insulating layer and a first gate electrode formed on the first gate insulating layer, wherein the first gate electrode includes a first metal alloy layer composed of a first metal and a second metal; and a second MOS transistor that has a second channel of a second conductivity type, a second insulating layer and a second gate electrode formed on the second gate insulating layer, wherein the second metal alloy layer is composed of a third metal and a fourth metal.

Example embodiments of the invention also include methods of fabricating CMOS semiconductor devices that include an NMOS transistor and a PMOS transistor, both having an appropriate threshold voltage depending on a channel type, and both exhibiting reliable gate insulating layers.

Example embodiments of the invention also include methods of fabricating such semiconductor devices including: forming a gate insulating layer on a substrate including a first MOS transistor region in which a first channel having a first conductivity type is formed and a second MOS transistor region in which a second channel of a second conductivity type is formed; forming a metal layer on the gate insulating layer in the first MOS transistor region and in the second MOS transistor region; selectively transforming the metal layer into a metal alloy layer in the first MOS transistor region; and forming a first gate electrode having the metal alloy layer in the first MOS transistor region and a second gate electrode including the metal layer in the second MOS transistor region.

Example embodiments of the invention also include methods of selectively transforming of the metal layer into the metal alloy layer in the first MOS transistor region including forming a metal oxide thin film on the metal layer in the first MOS transistor region and in the second MOS transistor region; removing a portion of the metal oxide thin film while ensuring that a residual portion of the metal oxide thin film remains in the first MOS transistor region; and performing a thermal process on a resulting structure including the remaining portion of the metal oxide thin film in the first MOS transistor region, thereby forming the metal alloy layer in the first MOS transistor region. Example embodiments of the invention include forming metal oxide thin films by depositing approximately 10 to 20 atomic layers, wherein each atomic layer will have a thickness generally corresponding to the dimensions of a single molecule of the deposited compound.

Example embodiments of the invention also include methods may further include forming a polysilicon layer on the metal alloy layer and on the metal layer. In these example embodiments, heat generated during the forming of the polysilicon layer may be used to perform the thermal process on the resulting structure including the remaining portion of the metal oxide thin film in the first MOS transistor region.

Other example embodiments of the invention also include methods of selectively transforming the metal layer into the metal alloy layer in the first MOS transistor region including forming a metal oxide thin film on the metal layer in the first MOS transistor region and in the second MOS transistor region; removing a portion of the metal oxide thin film such that a residual portion of the metal oxide thin film remains in the first MOS transistor region; forming an upper metal layer on the metal oxide thin film and on the metal layer; and performing a thermal process on a resulting structure including the upper metal layer, thereby forming the metal alloy layer in the first MOS transistor region. The upper metal layer may include a material identical to the material forming the metal layer. The semiconductor device fabricating method according to other example embodiments of the invention may further include forming a polysilicon layer on the upper metal layer.

Example embodiments of the invention also include methods of fabricating semiconductor devices, including: forming a gate insulating layer on a substrate including a first MOS transistor region where a first channel of a first conductivity type is formed and a second MOS transistor region where a second channel of a second conductivity type is formed; forming a first gate electrode in the first MOS transistor region, the first gate electrode including a first alloy layer in contact with the gate insulating layer; and forming a second gate electrode in the second MOS transistor region, the second gate electrode including a first conductive layer formed from a different material than the material of the first alloy layer.

Example embodiments of the invention also include methods of forming the first gate electrode which may include forming a first metal layer on the gate insulating layer; forming a first metal oxide layer on the first metal layer; and forming the first alloy layer from the first metal layer and the first metal oxide layer by performing a thermal process. Example embodiments of the invention also include methods of forming the second gate electrode by simultaneously forming the first conductive layer and the first metal layer from the same material.

Example embodiments of the invention also include methods of forming the second electrode may further include forming a second metal oxide layer on the first conductive layer using a material different from that used to form the first metal oxide layer and forming the second alloy layer from the first conductive layer and the second metal oxide layer using a thermal process.

Example embodiments of the invention also include methods of forming the first gate electrode which may include forming a first metal layer on the gate insulating layer; forming a first metal oxide layer on the first metal layer; forming a second metal layer on the first metal oxide layer; and forming the first alloy layer from the first metal layer, the first metal oxide layer and the second metal layer using a thermal process.

Example embodiments of the invention also include methods of forming a first conductive layer for the second gate electrode that includes a dual structure with a lower conductive layer and an upper conductive layer. In such embodiments forming the first conductive layer of the second gate electrode may include simultaneously forming the lower conductive layer and the first metal layer from a first material and the simultaneously forming the upper conductive layer and the second metal layer from a second material wherein the first and second materials have different compositions.

CMOS devices fabricated according to the example embodiments of the invention will include NMOS transistors and PMOS transistors in which the respective threshold voltages are controlled, in part, by the channel-specific utilization of different conductive compositions to improve the threshold voltage control while improving or maintaining the reliability of the underlying gate insulating layers in both the NMOS and PMOS transistors.

### BRIEF DESCRIPTION OF THE DRAWINGS

Example embodiments of the methods that may be utilized in practicing the invention and example embodiments of the semiconductor devices incorporating such structures are addressed more fully below with reference to the attached drawings in which:

FIG. 1 is a sectional view of a CMOS semiconductor device of a semiconductor device according to an example embodiment of the invention;

FIG. 2 is a sectional view of a CMOS semiconductor device of a semiconductor device according to another example embodiment of the invention;

FIG. 3 is a sectional view of a CMOS semiconductor device of a semiconductor device according to another example embodiment of the invention;

FIG. 4 is a sectional view of a CMOS semiconductor device according to another example embodiment of the invention;

FIGS. 5A through 5F are sectional views illustrating a method of forming a CMOS semiconductor device of a semiconductor device according to an example embodiment of the invention;

FIGS. 6A through 6G are sectional views illustrating a method of forming a CMOS semiconductor device of a semiconductor device according to another example embodiment of the invention;

FIGS. 7A through 7F are sectional views illustrating a method of forming a CMOS semiconductor device of a semiconductor device according to another example embodiment of the invention;

FIG. 8 illustrates capacitance-voltage (C-V) curves for gate structures of semiconductor devices according to embodiments of the invention;

FIG. 9 is a graph of flat band voltage (V_{fb}) change according to the number of atomic layer deposition (ALD) cycles applied to form an Al₂O₃ layer in the gate structure of the semiconductor device according to an example embodiment of the invention;

FIG. 10 is a graph of capacitance equivalent thickness (CET) change according to the number of the ALD cycles used to form the Al₂O₃ layer in the gate structure of the semiconductor device according to an example embodiment of the invention;

FIG. 11 is a graph of leakage current according to voltage for various numbers of the ALD cycles used to form the Al₂O₃ layer in the gate structure of the semiconductor device according to an example embodiment of the invention;

FIG. 12 illustrates C-V curves for various gate structures to analyze effects of the Al₂O₃ layer position in the gate structure of the semiconductor device according to another example embodiment of the invention;

FIG. 13A is a graph illustrating a secondary ion mass spectroscopy (SIMS) analysis result after a gate structure is formed according to another example embodiment of the invention; and

FIG. 13B is a graph illustrating a SIMS analysis result after an annealing process is performed on the gate structure used to obtain the results shown in FIG. 13A.

It should be noted that these Figures are intended to illustrate the general characteristics of methods and materials with reference to certain example embodiments of the invention and thereby supplement the detailed written description provided below. These drawings are not, however, to scale and may not precisely reflect the characteristics of any given embodiment, and should not be interpreted as defining or limiting the range of values or properties of embodiments within the scope of this invention. In particular, the relative thicknesses and positioning of layers or regions may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

The invention will now be described more fully with reference to the accompanying drawings, in which certain example embodiments of the invention are shown. As will be appreciated by those skilled in the art, the invention may be embodied in many different forms and should not be construed as being limited to the specific example embodiments set forth herein. Indeed, these embodiments are provided for supplementing the detailed description provided below and ensure that the disclosure is sufficient to allow those skilled in the art to understand and practice the invention. Again, as is conventional with drawings illustrating semiconductor fabrication processes, the relative thicknesses of layers and regions may be adjusted to improve clarity and are not necessarily proportional to or reflective of the range of actual thicknesses that can be utilized successfully in practicing the invention.

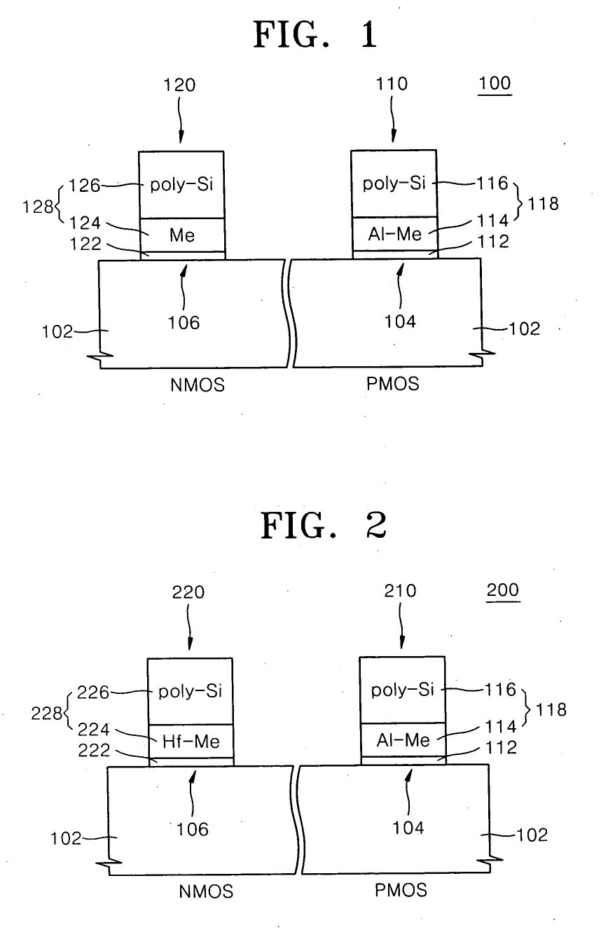

FIG. 1 is a sectional view of a CMOS semiconductor device 100 according to an example embodiment of the invention. As illustrated in FIG. 1, the CMOS device 100 incorporated both a PMOS transistor 110 formed on a PMOS region of a substrate 102 denoted as “PMOS,” wherein a P-type channel is formed in a first channel region 104, and an NMOS transistor 120 formed on an NMOS region of the substrate denoted as “NMOS,” wherein an N-type channel is formed at a second channel region 106.

The PMOS transistor 110 includes a first gate insulating layer 112 and a first gate electrode 118. The first gate electrode 118 includes an aluminium-metal (Al—Me) alloy layer 114 formed on the first gate insulating layer 112, and a first doped polysilicon layer 116 formed on the Al—Me alloy layer 114. The first gate insulating layer 112 can include silicon dioxide (SiO₂) or silicon oxynitride (SiON). The Al—Me alloy layer 114 can include an Al-tantalum nitride (TaN) alloy, in which case. Si—O—Al bonds are created at an interface between the Al—Me alloy layer 114 and the first gate insulating layer 112, thereby providing a work function appropriate for a PMOS transistor. Depending on the capabilities of the metallurgical processes utilized to form sufficiently thin and uniform layers, other Al—Me alloy layers may be formed including, for example, TaN/Ta/Al₂O₃, TaN/AlN, or TaN/Al—Si. Other metals and metal compounds may also be incorporated in such stacked structures including, for example, titanium (Ti), hafnium (Hf), zirconium (Zr), lanthanum (La), and molybdenum (Mo), as well as nitrides and carbides of such metals.

The NMOS transistor 120 includes a second gate insulating layer 122 and a second gate electrode 128. The second gate electrode 128 includes a metal layer 124 formed on the second gate insulating layer 122, and a second doped polysilicon layer 126 formed on the metal layer 124. The second gate insulating layer 122 can include SiON or SiO₂. The metal layer 124 can include a material identical to a metal component of the Al—Me alloy layer 114, e.g., TaN.

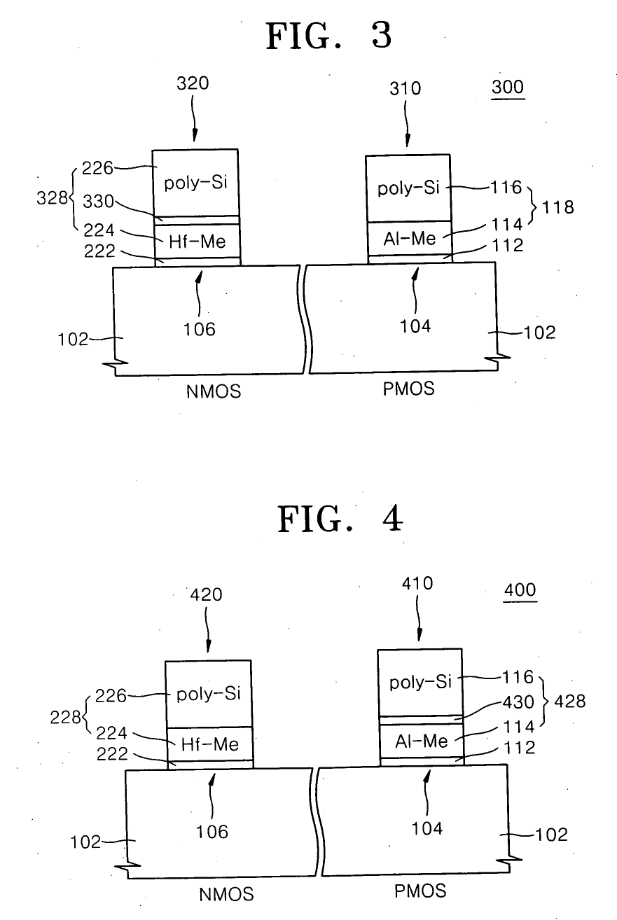

FIG. 2 is a sectional view of a CMOS semiconductor device 200 according to another example embodiment of the invention. The CMOS semiconductor device 200 includes a PMOS transistor 210, which has the same configuration as the PMOS transistor 110 illustrated in FIG. 1 and detailed above. Accordingly, a detailed description of PMOS transistor 210 will be omitted. The CMOS semiconductor device 200 further includes an NMOS transistor 220 provided with a third gate insulating layer 222 and a third gate electrode 228. The third gate electrode 228 includes a hafnium-metal (Hf—Me) alloy layer 224 formed on the third gate insulating layer 222, and a second doped polysilicon layer 226 formed on the Hf—Me alloy layer 224. The third gate insulating layer 222 can include SiON or SiO₂. The Hf—Me alloy layer 224 can include an Hf—TaN alloy, in which case Si—Hf bonds are created at an interface between the Hf—Me alloy layer 224 and the third gate insulating layer 222, thereby providing a work function appropriate to NMOS transistors.

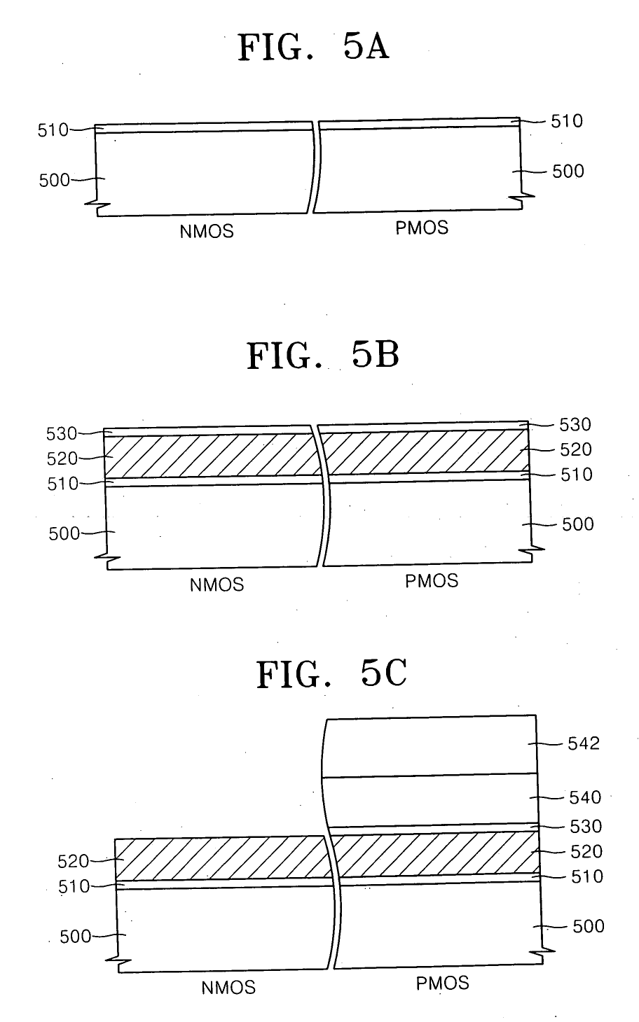

FIG. 3 is a sectional view of a CMOS semiconductor device 300 according to another example embodiment of the invention. As illustrated in FIG. 3, the CMOS semiconductor device 300 includes a PMOS transistor 310 and an NMOS transistor 320 having configurations that correspond generally to the PMOS transistor 210 and the NMOS transistor 220, respectively, described above. However, the NMOS transistor 320 of the CMOS semiconductor device 300 according to this example embodiment includes a fourth gate electrode 328, which further includes an Al—Hf—Me alloy layer 330 interposed between the Hf—Me alloy layer 224 and the second doped polysilicon layer 226. The Al—Hf—Me alloy layer 330 can be an Al—Hf—Ta alloy.

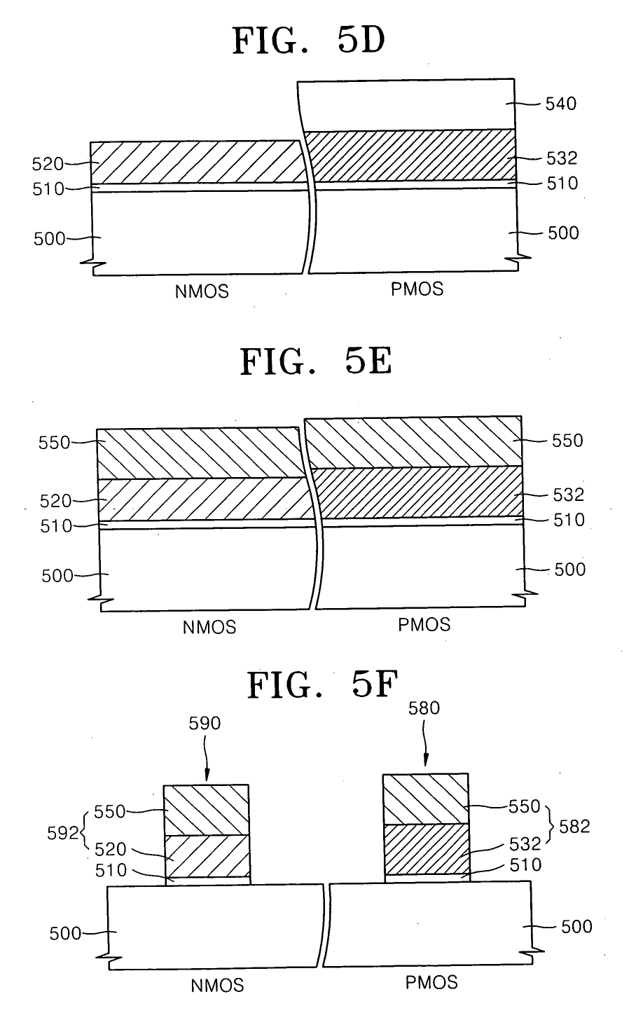

FIG. 4 is a sectional view of a CMOS semiconductor device 400 according to another example embodiment of the invention. As illustrated in FIG. 4, the CMOS semiconductor device 400 includes a PMOS transistor 410 and an NMOS transistor 420 having configurations that correspond generally to the PMOS transistor 210 and the NMOS transistor 220, respectively, described above. However, the PMOS transistor 410 of the CMOS semiconductor device 400 according to this example embodiment includes a fifth gate electrode 428, which further includes an Al—Hf—Me alloy layer 430 interposed between the Al—Me alloy layer 114 and the first doped polysilicon layer 116. The Al—Hf—Me alloy layer 430 can be an Al—Hf—Ta alloy.

In the CMOS semiconductor devices described in the four example embodiments of the invention detailed above, silicon (Si) contained within each of the gate insulating layers 112, 122 and 222 binds with a metal contained within each of the first to the fifth gate electrodes 118, 128, 228, 328, and 428, with the resulting Si-metal bond inducing Fermi-level pinning, which causes a corresponding increase or decrease in a threshold voltage (Vₜ) of the NMOS and PMOS transistors. Using these corresponding increases or decreases in the threshold voltage caused by the Fermi-level pinning, gate electrodes may be fabricated with different work functions for securing desired operational characteristics of the respective PMOS and NMOS transistors. In the PMOS transistor, for example, Si—O—Al bonds are formed at an interface between a gate insulating layer and a gate electrode structure, as required. Conversely, in the NMOS transistor, for example, Si—Hf bonds are formed at in interface between a gate insulating layer and a gate electrode structure, as required. In terms of operational characteristics of the individual PMOS and NMOS transistors, the gate electrode structures are configured to provide different work functions and thereby allow the threshold voltages of the respective PMOS transistors and the NMOS transistors to be controlled to within a desired range.

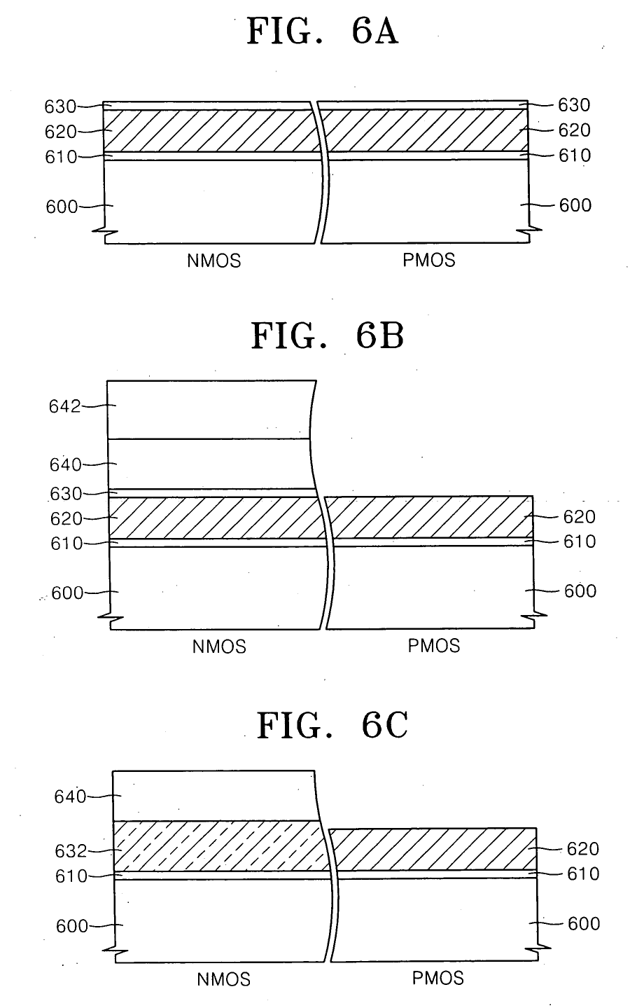

FIGS. 5A through 5F are sectional views illustrating a method of forming a CMOS semiconductor device according to an example embodiment of the invention. In particular, FIGS. 5A through 5F illustrate a method of fabricating a CMOS semiconductor device having a structure corresponding to the CMOS semiconductor device 100 illustrated above in FIG. 1.

As illustrated in FIG. 5A, a gate insulating layer 510 is formed on a substrate 500 (e.g., a silicon substrate) including a PMOS region and an NMOS region. The gate insulating layer 510 can be formed to a thickness of, for example, 10 Å to 30 Å from an appropriate dielectric, for example, SiON or SiO₂. As illustrated in FIG. 5B, a metal layer 520 is formed on the gate insulating layer 510. The metal layer 520 may include TaN and can be formed to a thickness of, for example, 30 Å to 50 Å.

A metal oxide layer 530, for example, Al₂O₃, is then formed on the metal layer 520. The metal oxide layer 530 can be formed by performing multiple cycles, typically several cycles to several tens of cycles of an ALD method, to obtain a layer of sufficient thickness. For example, the metal oxide layer 530 can be formed as a thin film by performing 5 to 30 cycles of the ALD method.

As illustrated in FIG. 5C, a hard mask layer (not shown), for example, a SiO₂ layer, is formed on the metal oxide layer 530. A photoresist pattern 542 is then formed to cover the PMOS region. A portion of the hard mask layer covering the NMOS region is removed by using the photoresist pattern 542 as an etch mask, thereby forming a hard mask pattern 540 that covers the PMOS region.

Using the hard mask pattern 540 as an etch mask, a portion of the metal oxide layer 530 exposed in the NMOS region is selectively removed by, for example, a wet etching method utilizing a hydrogen fluoride (HF) solution, a low ammonium fluoride liquid (LAL) solution or another etch solution exhibiting sufficient etch selectivity to the metal oxide in question. HF solutions, for example, typically provide good etch selectivity with respect to TaN and thus, the Al₂O₃ layer can be removed. Because the metal oxide layer 530 is formed on the metal layer 520, the gate insulating layer 510 is protected during the wet etch processing to remove the metal oxide from the NMOS region.

As illustrated in FIG. 5D, an ashing and stripping process or other conventional process is then employed to remove the photoresist pattern 542 and then a thermal process is performed on the resulting structure at a temperature sufficient to induce a reaction between the metal layer 520 and the metal oxide layer 530 in the PMOS region. As a result of this thermal process, an alloy layer 532 is formed on the gate insulating layer 510 in the PMOS region. The thermal process used to form the alloy layer 532 will depend on the materials selected, but may typically be performed at a temperature ranging from approximately 600° C. to 800° C. In those instances in which the metal layer 520 includes TaN and the metal oxide layer 530 includes Al₂O₃, the thermal processing will form a Al—TaN alloy layer 532 through a combination of diffusion and/or reactive processes. Although not illustrated, an unreacted portion of the metal oxide layer 530 may remain on the alloy layer 532 after the thermal processing.

As illustrated in FIG. 5E, the hard mask pattern 540 is then removed and a doped polysilicon layer 550 is formed on both the metal layer 520 in the NMOS region and the alloy layer 532 in the PMOS region. The thickness of the doped polysilicon layer 550 may range, for example, from approximately 1,000 Å to 2,000 Å. As will be appreciated by those skilled in the art, the polysilicon layer thickness may be adjusted as necessary to adapt the process to evolving design rules. As will also be appreciated by those skilled in the art, the presence of a thin metal oxide layer in the structures described above will not tend to compromise the performance of the final device unduly, but residual metals or metal oxides may produce devices that exhibit some increase in the work function of the resulting electrode.

Although as described with reference to FIG. 5D, the alloy layer 532 may be formed using a separate thermal process, depending on the conditions utilized during the formation of the doped polysilicon layer 550, the polysilicon deposition process may provide a temperature for a duration sufficient to induce the reaction between the metal layer 520 and the metal oxide layer 530 to form the alloy layer 532. In such instances, the separate thermal process described with reference to FIG. 5D can be omitted or modified whereby the combination of the thermal process and the polysilicon deposition provide the necessary thermal conditions to form the alloy layer 532. When the thermal process is omitted, the alloy layer 532 and the doped polysilicon layer 550 can be formed simultaneously.

As illustrated in FIG. 5F, a gate patterning process is then performed in the PMOS region and in the NMOS region. In the PMOS region, the gate patterning process produces a PMOS transistor 580 having a first gate electrode 582 having a stacked structure that includes both the alloy layer 532 and the doped polysilicon layer 550 formed on the gate insulating layer 510. Conversely, in the NMOS region, the gate patterning process produces an NMOS transistor 590 having a second gate electrode 592 having a stacked structure that includes the metal layer 520 and the doped polysilicon layer 550 on the gate insulating layer 510.

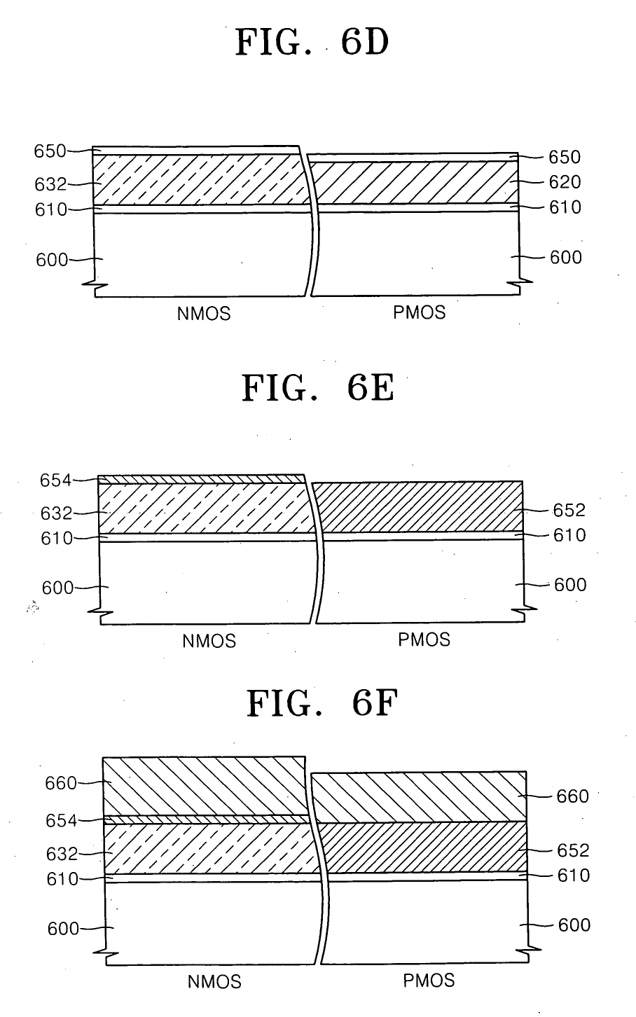

FIGS. 6A through 6G are sectional views illustrating a method of forming a CMOS semiconductor device according to another example embodiment of the invention. In particular, FIGS. 6A through 6G illustrate an example embodiment of a method for fabricating a CMOS semiconductor device having a structure generally corresponding to the CMOS semiconductor device 300 illustrated in FIG. 3.

As illustrated in FIG. 6A, a gate insulating layer 610, a metal layer 620 and a first metal oxide layer 630 are sequentially formed on a substrate 600 (e.g., a silicon substrate) that includes both PMOS region and NMOS regions. This process is performed in the manner previously described with reference to FIGS. 5A and 5B and includes a first metal oxide layer 630 comprising HfO₂, a gate insulating layer 610 that can include SiON or SiO₂ and metal layer 620 that can include, for example, TaN.

As illustrated in FIG. 6B, a hard mask layer (not shown), e.g., a SiO₂ layer, is formed on the first metal oxide layer 630 after which a photoresist pattern 642 is formed to protect the NMOS region while a portion of the hard mask layer covering the PMOS region is removed, thereby forming a hard mask pattern 640 that covers the NMOS region. Using the hard mask pattern 640 as an etch mask, a portion of the first metal oxide layer 630 exposed in the PMOS region is selectively removed by using, for example, a wet etch. Because the first metal oxide layer 630 is formed on the metal layer 620, the gate insulating layer 610 is not exposed to the etch, thereby suppressing or avoiding damage to the gate insulating layer during the etch process.

As illustrated in FIG. 6C, the photoresist pattern 642 is removed by an ashing and stripping process or any other conventional photoresist removal technique. A thermal process may then be performed on the resulting structure at a temperature sufficient to induce a reaction between the metal layer 620 and the first metal oxide layer 630 in the NMOS region to form a first alloy layer 632 on the gate insulating layer 610. The temperature necessary for the thermal process will depend on the materials used, but may typically be in a range of approximately 600° C. to 800° C. When the metal layer 620 includes TaN and the first metal oxide layer 630 includes HfO₂, the first metal alloy layer 632 produced by the thermal process will be a Hf—TaN alloy. Although not shown in FIG. 6C, an unreacted portion of the first metal oxide layer 630 may remain on the first alloy layer 632.

As illustrated in FIG. 6D, the hard mask pattern 640 is then removed and a second metal oxide layer 650 is formed on both the first alloy layer 632 in the NMOS region and on the metal layer 620 in the PMOS region. The second metal oxide layer 650 can be formed using a material such as Al₂O₃. The second metal oxide layer 650 can be formed using the method used to form the metal oxide layer 530 as described above with reference to FIG. 5B.

As illustrated in FIG. 6E, another thermal process is then performed on the resulting structure at a temperature sufficient to induce a reaction between the metal layer 620 and the second metal oxide layer 650 in the PMOS region. As a result of this thermal processing, a second alloy layer 652 is formed on the gate insulating layer 610 in the PMOS region. The thermal process for forming the second alloy layer 652 will depend on the materials selected, but can typically be performed at a temperature ranging from approximately 600° C. to 800° C. When, for example, the metal layer 620 includes TaN and the second metal oxide layer 650 includes Al₂O₃, the second alloy layer 652 formed by the thermal processing will be an Al—TaN alloy. During the formation of the second alloy layer 652, a third alloy layer 654 is simultaneously formed on the first alloy layer 632 in the NMOS region. The third alloy layer 654 can be an Al—Hf—TaN alloy. Although not illustrated, an reacted portion of the second metal oxide layer 650 may remain on the second alloy layer 652 and on the third alloy layer 654 after the completion of the thermal processing.

As illustrated in FIG. 6F, a doped polysilicon layer 660 is formed on the second alloy layer 652 in the PMOS region and on the third alloy layer 654 in the NMOS region. The doped polysilicon layer 660 has a thickness of approximately 1,000 Å to 2,000 Å. As will be appreciated by those skilled in the art, the polysilicon layer thickness may be adjusted as necessary to adapt the process to evolving design rules.

The thermal process described with reference to FIG. 6D for forming the second alloy layer 652 and the third alloy layer 654 can be omitted for the reason described with reference to FIG. 5E when the thermal processing associated with the formation of the doped polysilicon layer 660 is sufficient to induce the desired reaction between the second alloy layer 652 and the third alloy layer 654. In such an embodiment, the second alloy layer 652 and the third alloy layer 654 can be formed as simultaneously during the formation of the doped polysilicon layer 660.

As illustrated in FIG. 6G, a gate patterning process is performed in the NMOS region and in the PMOS region. The gate patterning process produces a PMOS transistor 680 including a first gate electrode 682 having a stacked structure that includes the second alloy layer 652 and the doped polysilicon layer 660 on the gate insulating layer 610 in the PMOS region. The gate patterning process also produces an NMOS transistor 690 including a second gate electrode 692 having a stacked structure that includes the first alloy layer 632, the third alloy layer 654 and the doped polysilicon layer 660 sequentially formed on the gate insulating layer 610 in the NMOS region.

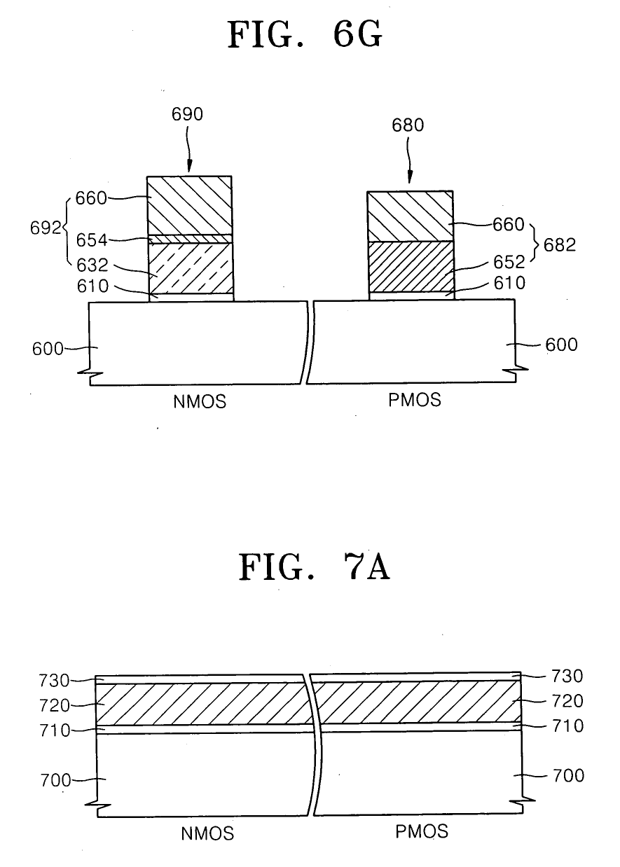

FIGS. 7A through 7F are sectional views illustrating a method of forming a CMOS semiconductor device according to another example embodiment of the invention. In particular, FIGS. 7A through 7F illustrate another method of fabricating a CMOS semiconductor device having a structure generally corresponding to the CMOS semiconductor device 100 described above with reference to FIG. 1.

As illustrated in FIG. 7A, a gate insulating layer 710, a first metal layer 720 and a metal oxide layer 730 are sequentially formed on a substrate 700 (e.g., a silicon substrate) including an NMOS region and a PMOS region. The gate insulating layer 710 can include, for example, SiON or SiO₂, the first metal layer 720 can include a metal nitride, for example, TaN, and the metal oxide layer 730 can include, for example, Al₂O₃.

As illustrated in FIG. 7B, using a photoresist pattern 742 covering the PMOS region, a portion of the metal oxide layer 730 exposed in the NMOS region is selectively removed by, for example, a wet etching method using a solution of HF. Because the metal oxide layer 730 is formed on the first metal layer 720, the gate insulating layer 710 will not be exposed to the etch during this process, thereby reducing or eliminating damage to the gate insulating layer during the etch process.

As illustrated in FIG. 7C, an ashing and stripping process or other conventional photoresist removal process is then performed to remove the photoresist pattern 742 from the PMOS region. As illustrated in FIG. 7D, a second metal layer 750 is then formed on both the metal oxide layer 730 in the PMOS region and on the first metal layer 720 in the NMOS region. The second metal layer 750 can include a metal nitride, for example, a TaN or another refractory metal or metal nitride. Thus, the metal oxide layer 730 is disposed between the first metal layer 720 and the second metal layer 750 in the PMOS region while in the NMOS region, the stacked structure includes only the first metal layer 720 and the second metal layer 750.

As illustrated in FIG. 7E, a doped polysilicon layer 760 is formed on the second meal layer 750 in the PMOS and NMOS regions. The doped polysilicon layer 760 can be formed to a thickness of approximately 1,000 Å to 2,000 Å. As will be appreciated by those skilled in the art, the polysilicon layer thickness may be adjusted as necessary to adapt the process to evolving design rules.

Thermal budget or thermal cycle to which the underlying structures are exposed during formation of the doped polysilicon layer 760 will typically be sufficient to induce a reaction between the first metal layer 720, the metal oxide layer 730 and the second metal layer 750, thereby forming an alloy layer 732. Although not shown, an unreacted portion of the metal oxide layer 730 can remain within the alloy layer 732.

Alternatively, prior to forming the doped polysilicon layer 760, the thermal process described above with reference to FIG. 5D can be performed to induce the reaction between the first metal layer 720, the metal oxide layer 730 and the second metal layer 750. Similarly, a separate thermal process performed before or after the deposition of the doped polysilicon layer may be used, in combination with the polysilicon deposition, to achieve the desired degree of reaction between the various metal and metal oxide layers to produce the metal alloy layer 732.

As illustrated in FIG. 7F, a gate patterning process is then performed in the PMOS and NMOS regions. The gate patterning process in the PMOS region produces a PMOS transistor 780 including a first gate electrode 782 having a stacked structure that includes the alloy layer 732 and the doped polysilicon layer 760 on the gate insulating layer 710. The gate patterning process in the NMOS region provides an NMOS transistor 790 including a second gate electrode 792 having a stacked structure that includes the first metal layer 720, the second metal layer 750 and the doped polysilicon layer 760 formed on the gate insulating layer 710.

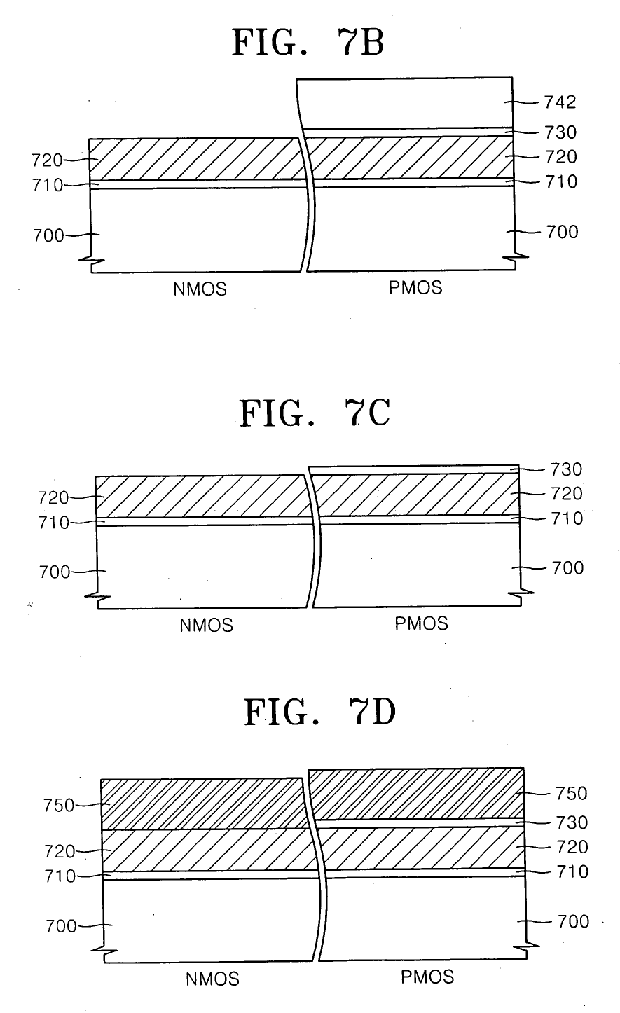

FIG. 8 is a graph of C-V curves for gate structures of semiconductor devices according to embodiments of the invention. The C-V data presented in FIG. 8 was collected from a device fabricated by forming a SiON gate insulating layer having a thickness of approximately 18 Å on a silicon substrate and then forming a gate electrode having a TaN/Al₂O₃/TaN stacked structure on the gate insulating layer. In the gate electrode structure, the TaN layer was formed to a thickness of approximately 40 Å, and the Al₂O₃ layer was obtained by performing an ALD method with various numbers of ALD cycles. The C-V data was then collected to determine the flat band voltage (V_{fb}) of the metal oxide semiconductor capacitor (MOSCAP) structures obtained using the gate electrode structure formation method described above. FIG. 8 illustrates the experimental results when the Al₂O₃ layers were obtained individually by performing 10, 15, 20, and 25 cycles of the ALD method. The gate electrodes formed using the TaN/Al₂O₃/TaN stacked structure exhibit a greater flat band voltage than gate electrodes formed using TaN only. These experimental results confirm that using a gate electrode having the TaN/Al₂O₃/TaN stacked structure for PMOS transistors allows the threshold voltage (Vₜ) to be decreased.

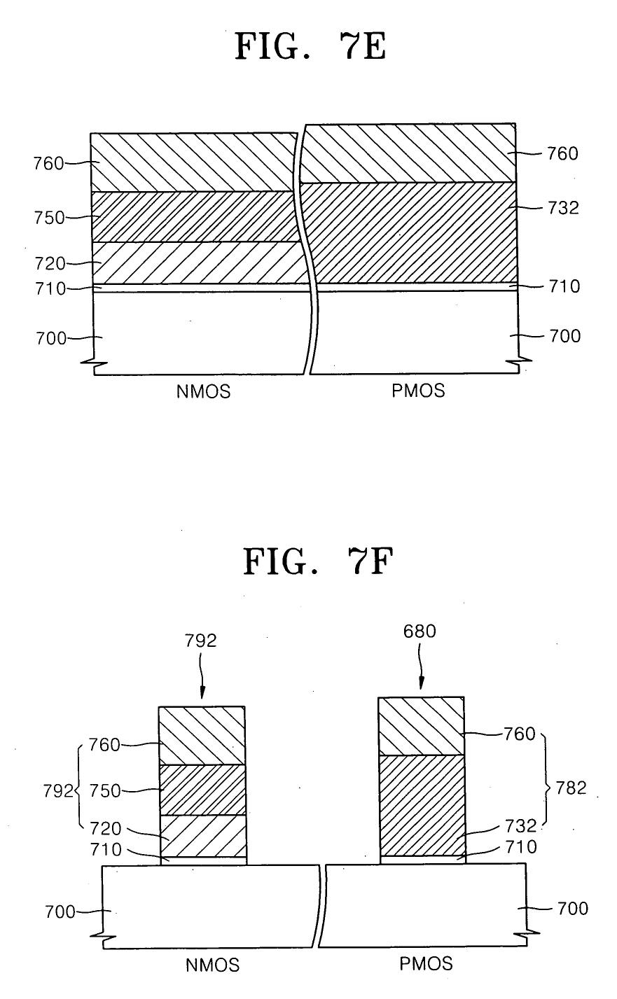

FIG. 9 is a graph of flat band voltage change, ΔV_{fb}, plotted against the number of ALD cycles utilized in forming the Al₂O₃ layer of the MOSCAP structure used for collecting the data presented in FIG. 8. The flat band voltage change ΔV_{fb} is calculated by subtracting a flat band voltage (V_{fb}) measured when the single TaN layer was used as the gate electrode from a flat band voltage (V_{fb}) measured from the MOSCAP structure according to example embodiments of the invention.

As illustrated in FIG. 9, as the number of the ALD cycles increases, the flat band voltage change ΔV_{fb} also gradually increases before reaching a plateau at approximately 15 ALD cycles. The flat band voltage change ΔV_{fb} across the plateau region, i.e., where the Al₂O₂ layer includes at least 14-15 ALD layers, is approximately 0.53 V.

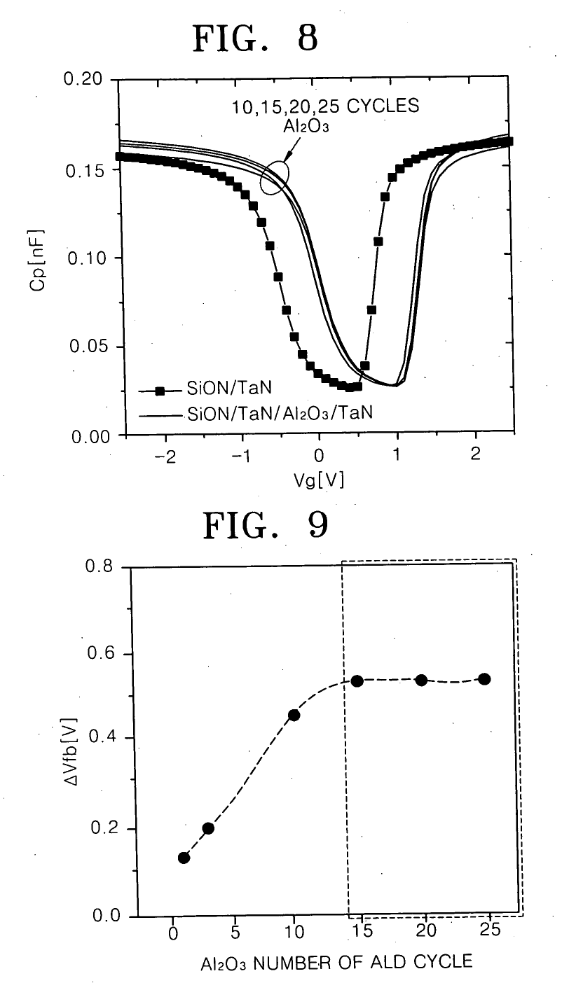

FIG. 10 is a graph of the capacitance equivalent thickness (CET) change plotted against the number of ALD cycles utilized in forming the Al₂O₃ layer included in the MOSCAP stacked structure used in forming the capacitors used for collecting the C-V data presented in FIG. 8. The CET change is denoted as ACET in FIG. 10 as calculated by subtracting CET values measured using a gate electrode formed from a single TaN layer from CET values measured using a gate electrode formed with a TaN/Al₂O₃/TaN stacked structure.

As illustrated in FIG. 10, the CET changed according to the number of ALD cycles used to form the Al₂O₃ layer with the maximum decrease of approximately 0.2 nm being obtained with an Al₂O₃ layer formed after approximately 20 cycles of the ALD method were performed. As also illustrated in FIG. 10, the ACET then increased for gate electrode structures incorporating Al₂O₃ layers formed when more than approximately 20 cycles of the ALD method were performed.

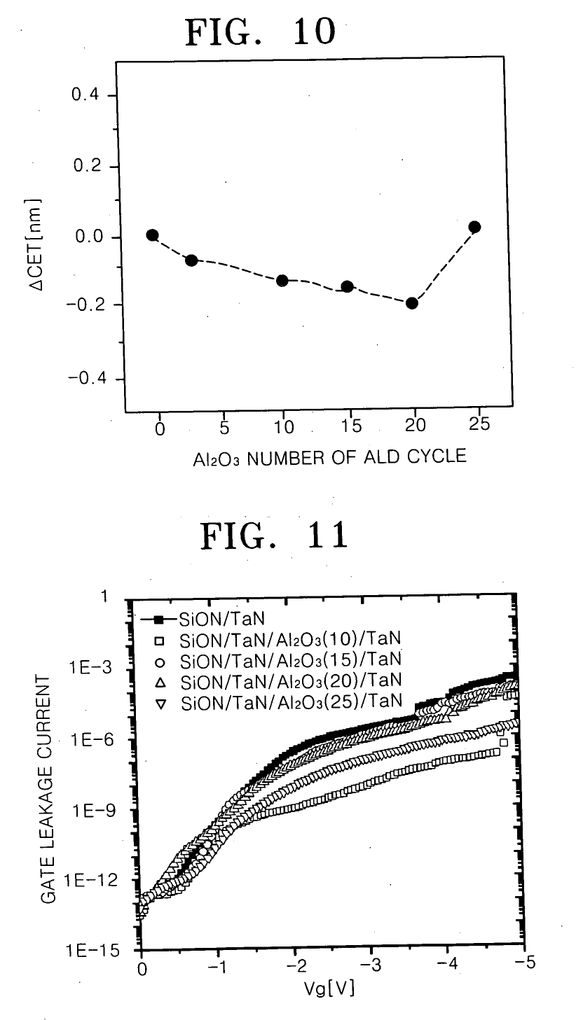

FIG. 11 is a graph of leakage current versus gate voltage (V_{g}) for MOSCAP structures in which various numbers of ALD cycles, i.e., 10, 15, 20 and 25 cycles, were utilized in forming the Al₂O₃ layer of a MOSCAP structure as detailed above with reference to FIG. 8. As illustrated in FIG. 11, there was little, if any, increase in the leakage current for those structures incorporating a gate electrode having a TaN/Al₂O₃/TaN stacked structure.

According to the results shown in FIGS. 9 through 11, in those instances in which 10 to 20 ALD cycles are utilized in forming the Al₂O₃ layer of the stacked gate electrode structure including a lower TaN layer, an intermediate Al₂O₃ layer and an upper TaN layer is in a range of approximately 10 to 20, improved control over the flat band voltage modulation may be obtained whereby the threshold voltage of the MOS transistors can be decreased without also increasing the CET.

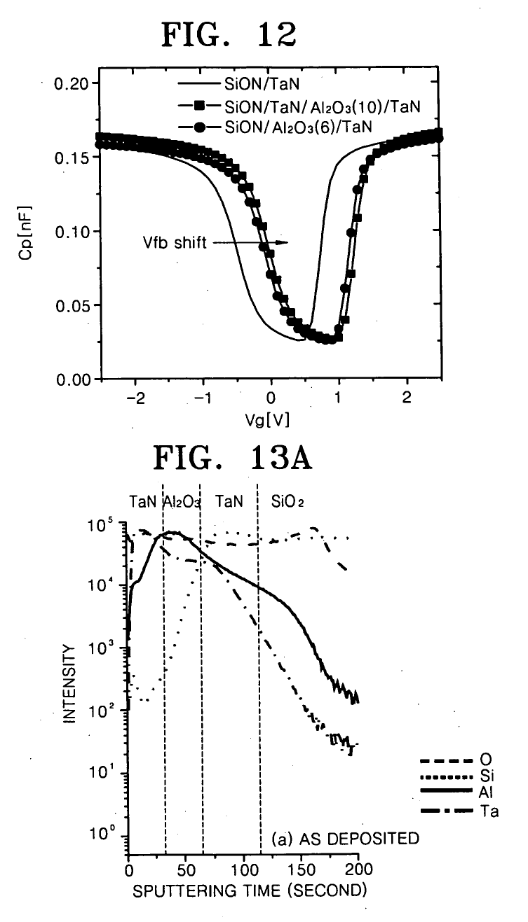

FIG. 12 is a graph illustrating a collection of C-V curves corresponding to various gate structures utilized in forming semiconductor devices according to another example embodiment of the invention. One C-V curve was obtained when the gate electrode having a TaN/Al₂O₃/TaN structure was formed on a SiON gate insulating layer with another C-V curve being was obtained when the gate electrode having an Al₂O₃/TaN structure was formed on a SiON gate insulating layer. As illustrated in FIG. 12, in comparison to the gate electrode having a single TaN layer (line), both the TaN/Al₂O₃/TaN stack structure (plotted as ▪) and the Al₂O₃/TaN stack structure (plotted as ●) exhibited similar increases in the flat band voltage (V_{fb}). Whether the Al₂O₃ layer was formed directly on the gate insulating layer or on a lower TaN layer, the resulting capacitors exhibited similar flat band voltage (V_{fb}) increases. Without being bound by theory, it is believed that when the gate electrode is formed with the TaN/Al₂O₃/TaN structure, Al atoms diffuse to an interface between the SiON layer and the TaN layer and thereby generate Si—O—Al bonds at this interface and increasing the flat band voltage (V_{fb}) above that which is obtained using the single TaN gate electrode structure.

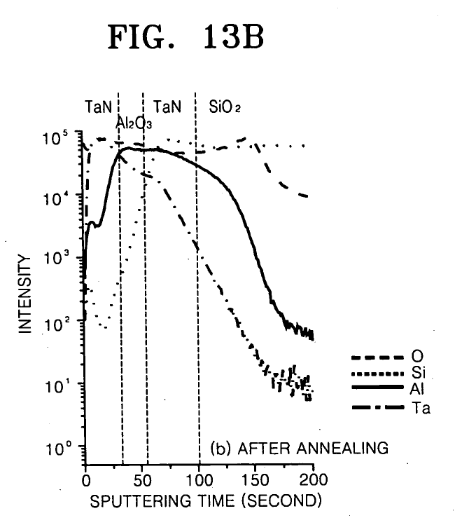

FIG. 13A illustrates the results of a SIMS analysis performed after formation of the stacked gate electrode structure TaN/Al₂O₃/TaN corresponding to the electrode structures used in obtaining the results reflected above in FIG. 8 but using a SiO₂ gate dielectric rather than a SiON gate dielectric. FIG. 13B illustrates the results of a SIMS analysis on a corresponding stacked gate electrode structure after having been annealed at a temperature of approximately 700° C. for approximately 30 seconds.

Comparing the SIMS profile illustrated in FIG. 13A with the SIMS profile illustrated in FIG. 13B reflects changes in the Al profile induced by the annealing process. As reflected by the change between FIG. 13A and FIG. 13B, during the annealing process, Al atoms diffused from the Al₂O₃ layer to the interface between the SiO₂ dielectric layer and the lower TaN layer.

The NMOS and PMOS transistors incorporated in the CMOS semiconductor devices according to the example embodiments of the invention utilize metals and combinations of metals having different work functions in their respective gate electrodes. This Fermi-level pinning resulting from Si-metal bonds produced by using materials that can generate Si—O—Al bonds or Si—Hf bonds at the interface between the gate electrode structure and the gate insulating layer depending on the channel type of the MOS transistors. Using different gate electrode structures on the PMOS and NMOS channel devices improves the control over the threshold voltages of the final NMOS and PMOS transistors. Other example embodiments of the invention provide improved methods for fabricating CMOS semiconductor devices capable of producing NMOS and PMOS transistors having channel-specific gate electrode structures that provide improved control over the corresponding threshold voltages while maintaining or improving the reliability of the gate insulating layer.

Although the example embodiments described above disclose CMOS semiconductor devices having channel-specific gate electrode structures and methods of fabricating such CMOS semiconductor devices, those skilled in the art will appreciate that these techniques and structures may also be adapted for use in the fabrication of other semiconductor devices that do not incorporate a CMOS configuration and/or that combine CMOS circuitry with other structures, for example, BiCMOS.

While the invention has been particularly shown and described with reference to example embodiments thereof, it will be understood by those of ordinary skill in the art that various changes in form and details may be made therein without departing from the spirit and scope of the invention as defined by the following claims.

What is claimed is:

1. A CMOS semiconductor device, comprising:
a first MOS transistor having a first channel region of a first conductivity type formed in a semiconductor substrate, a first region of a gate insulating layer formed on the first channel region, and a first gate electrode formed on the first gate insulating layer, wherein the first gate electrode includes a first stacked conductive structure metal alloy layer and is configured to provide a first work function Φ₁; and
a second MOS transistor having a second channel region of a second conductivity type formed in the semiconductor substrate, a second region of the gate insulating layer formed on the second channel region, and a second electrode formed on the second gate insulating layer, wherein the second gate electrode is configured to provide a second work function Φ₂, and further wherein the first and second work functions satisfy the expression Φ₁≠Φ₂.

2. The CMOS semiconductor device according to claim 1, wherein:
the first gate electrode includes a polysilicon layer formed on a first metal alloy layer, the first metal alloy including a first metal and a second metal.

3. The CMOS semiconductor device according to claim 2, wherein:
the first MOS transistor has first threshold voltage Vₜₕ₁;
a third MOS transistor having a gate electrode that includes a metal layer consisting essentially of the first metal or the second metal has a third threshold voltage Vₜₕ₃, and further wherein the expression Vₜₕ₁<Vₜₕ₃ is satisfied.

4. The CMOS semiconductor device according to claim 2, wherein:
the first metal alloy includes aluminum (Al) as the first metal and tantalum (Ta) as the second metal.

5. The CMOS semiconductor device according to claim 2, wherein:
the first gate electrode includes a metal oxide layer formed on the first metal alloy layer.

6. The CMOS semiconductor device according to claim 5, wherein:
the metal oxide layer has a thickness of 10 to 20 atomic layers.

7. The CMOS semiconductor device according to claim 6, wherein:
the metal oxide thin film includes aluminum oxide (Al₂O₃).

8. The CMOS semiconductor device according to claim 2, wherein the second gate electrode further comprises:
a first conductive layer formed from one of the first metal, the second metal or the metal nitride.

9. The CMOS semiconductor device according to claim 8, wherein:
the conductive layer is TaN.

10. The CMOS semiconductor device according to claim 8, wherein:
the second gate electrode further comprises a polysilicon layer formed on the first conductive layer.

11. The CMOS semiconductor device according to claim 1, wherein the second gate electrode further comprises:
a second metal alloy layer having a composition different than the first metal alloy layer.

12. The CMOS semiconductor device according to claim 11, wherein:
the second metal alloy layer includes an alloy of hafnium (Hf) and tantalum (Ta).

13. The CMOS semiconductor device according to claim 11, wherein:
the second gate electrode further comprises a polysilicon layer formed on the second metal alloy layer.

14. The CMOS semiconductor device according to claim 13, wherein:
the second gate electrode further comprises a third metal alloy layer formed between the second metal alloy layer and the polysilicon layer and further wherein the third metal alloy has a different composition than the second metal alloy layer.

15. The CMOS semiconductor device according to claim 14, wherein:
the third metal alloy layer includes an alloy of aluminum (Al), hafnium (Hf) and tantalum (Ta).

16. The CMOS semiconductor device according to claim 8, wherein:
the gate insulating layer consists essentially of a dielectric material selected from a group consisting of silicon oxynitrides and silicon oxides.

17. The CMOS semiconductor device according to claim 11, wherein:
the gate insulating layer consists essentially of a dielectric material selected from a group consisting of silicon oxynitrides and silicon oxides.

18. The CMOS semiconductor device according to claim 1, wherein:
the first MOS transistor is a p-channel MOS transistor.

19. A CMOS semiconductor device, comprising:
a first MOS transistor having a first channel region of a first conductivity type formed in a semiconductor substrate, a first region of a gate insulating layer formed on the first channel region, and a first gate electrode formed on the first gate insulating layer, wherein the first gate electrode comprises a first metal alloy including a first metal and a second metal; and
a second MOS transistor having a second channel region of a second conductivity type formed in the semiconductor substrate, a second region of a gate insulating layer formed on the second channel region, and a second gate electrode formed on the second gate insulating layer, wherein the second gate electrode comprises a second metal alloy including a third metal and a fourth metal.

20. The CMOS semiconductor device according to claim 19, wherein:
one of the first metal and the second metal is identical to one of the third metal and the fourth metal.

21. The CMOS semiconductor device according to claim 20, wherein:
one of the first metal and the second metal includes tantalum; and
one of the third metal and the fourth metal includes tantalum.

22. The CMOS semiconductor device according to claim 19, wherein:
the first metal alloy layer includes an alloy of aluminum (Al), tantalum (Ta) and nitrogen (N);
and the second metal alloy layer includes an alloy of hafnium (Hf), tantalum (Ta) and nitrogen (N).

23. The CMOS semiconductor device according to claim 19, wherein:
the second gate electrode further comprises a third metal alloy layer formed on the second metal alloy layer, and further wherein the third metal alloy layer and the second metal alloy layer have different compositions.

24. The CMOS semiconductor device according to claim 23, wherein:
the third metal alloy layer includes aluminum (Al), hafnium (Hf) and tantalum (Ta).

25. The CMOS semiconductor device according to claim 19, wherein:
the first gate electrode further comprises a polysilicon layer formed on the first metal alloy layer; and
the second gate electrode further comprises a polysilicon layer formed on the second metal alloy layer.

26. The CMOS semiconductor device of claim 19, wherein:
both the first metal alloy layer provides a first work function Φ₁; and
the second metal alloy layer provides a second work function Φ₂, wherein the expression Φ₁≠Φ₂ is satisfied.

27. The CMOS semiconductor device according to claim 19, wherein:
the first metal is aluminum (Al); and
the third metal is TaN.

28. A method of fabricating a CMOS semiconductor comprising:
forming a first channel region having a first conductivity type and a second channel region having a second conductivity type in a semiconductor substrate;
forming a gate insulating layer in the first channel region and the second channel region;
forming a first conductive layer on the gate insulating layer, the first conductive layer comprising a first metal;
forming a first source layer on the first conductive layer, the first source layer comprising a second metal;
removing a portion of the first source layer formed above the first channel region; and
diffusing the second metal from first source layer through the first conductive layer to an interface between the first conductive layer and the gate insulating layer.

29. A method of fabricating a CMOS semiconductor device according to claim 28, wherein:
the gate insulating layer comprises a dielectric material selected from a group consisting of silicon oxides and silicon oxynitrides;
the first conductive layer comprises tantalum nitride (TaN); and
the first source layer comprises aluminum oxide (Al₂O₃).

30. A method of fabricating a CMOS semiconductor device according to claim 28, wherein:
forming a first source layer further comprises the atomic layer deposition (ALD) of from 10 to 20 layers of a metal compound;
diffusing the second metal further comprises heating the first source layer and the first conductive layer to a temperature of 600° C. to 800° C.
